(19) United States
(12) Patent Application Publication
(10) Pub. No.: US 2021/0276014 A1
(43) Pub. Date: Sep. 9, 2021

(54) FLUID HANDLING DEVICE

(71) Applicant: Enplas Corporation, Kawaguchi-shi (JP)

(72) Inventors: Seiichiro Suzuki, Saitama (JP); Yuichi Suzuki, Saitama (JP)

(21) Appl. No.: 17/187,909

(22) Filed: Mar. 1, 2021

(30) Foreign Application Priority Data
Mar. 6, 2020 (JP) 2020-038739

(51) Int. Cl. B01L 3/00

(52) U.S. Cl. CPC B01L 3/502784; B01L 2200/0673

(57) ABSTRACT

A fluid handling device of an embodiment of the present invention includes a sample channel configured to carry a sample; a dispersion medium channel configured to carry a dispersion medium; a dispersion liquid generation part connected to the sample channel and the dispersion medium channel and configured to generate dispersion liquid in which a droplet of the sample is dispersed in the dispersion medium by dividing the sample with the dispersion medium; a dispersion liquid channel connected to the dispersion liquid generation part and configured to carry the dispersion liquid; and a dispersion medium collection channel connected to the dispersion liquid channel and configured to collect the dispersion medium from the dispersion liquid flowing through the dispersion liquid channel.

### CROSS REFERENCE TO RELATED APPLICATIONS

This application is entitled to and claims the benefit of Japanese Patent Application No. 2020-038739, filed on Mar. 6, 2020, the disclosure of which including the specification, drawings and abstract is incorporated herein by reference in its entirety.

### TECHNICAL FIELD

The present invention relates to a fluid handling device.

### BACKGROUND ART

In clinical, food, and environmental testing, highly accurate analysis of trace amounts of analytes such as cells, proteins, and nucleic acids is often required. As a method of analyzing minute analytes, a method is known in which tiny droplets with a diameter of 0.1 to 1,000 μm are generated from a liquid containing the analyte and the droplets are observed and analyzed.

Droplets are generated by dividing the flowing sample in such a manner as to sandwich the flowing sample with oil. For example, PTL 1 discloses a method of generating droplets by ejecting a dispersion phase in an intersecting direction to a continuous phase flowing through a micro channel.

### CITATION LIST

### Patent Literature

PTL 1

WO2002/068104

### SUMMARY OF INVENTION

### Technical Problem

When generating droplets as described above, as the ratio of the oil flow rate to the sample flow rate (oil flow rate/sample flow rate) is increased, the flowing sample can be more reliably divided and the droplets can be more stably generated. Further, the size of generated droplets is more likely to be uniform.

While the generated droplets are typically collected and stored, the droplets are contained in oil since they are generated by being divided with the oil as described above and the droplets are collected together with the oil. As such, a storage tank for storing the droplets that is larger than the sum of the volume of generated droplets is required, and the collected droplets are likely to be contained in the oil with a relatively low concentration. Such a problem is especially pronounced when the proportion of the oil flow rate is increased as described above, for example.

Under the above-mentioned circumstances, an object of the present invention is to provide a fluid handling device that can more efficiently collect droplets.

### Solution to Problem

The present invention provides the following fluid handling device.

A fluid handling device of an embodiment of the present invention includes a sample channel configured to carry a sample; a dispersion medium channel configured to carry a dispersion medium; a dispersion liquid generation part connected to the sample channel and the dispersion medium channel and configured to generate dispersion liquid in which a droplet of the sample is dispersed in the dispersion medium by dividing the sample with the dispersion medium; a dispersion liquid channel connected to the dispersion liquid generation part and configured to carry the dispersion liquid; and a dispersion medium collection channel connected to the dispersion liquid channel and configured to collect the dispersion medium from the dispersion liquid flowing through the dispersion liquid channel.

### Advantageous Effects of Invention

According to the present invention, it is possible to provide a fluid handling device that can more efficiently collect droplets.

### BRIEF DESCRIPTION OF DRAWINGS

FIG. 1A is a plan view of a fluid handling device according to an embodiment of the present invention, and FIG. 1B is a sectional view taken along line B-B of FIG. 1A;

FIG. 2 is a bottom view of a substrate of the fluid handling device illustrated in FIG. 1A;

FIG. 3 is a partially enlarged perspective view of the substrate illustrated in FIG. 2; and

FIG. 4 is a drawing illustrating a state where droplets are generated at a dispersion liquid generation part.

### DESCRIPTION OF EMBODIMENTS

An embodiment of the present invention is elaborated below with reference to the accompanying drawings. Note that the size and ratio in the illustration in the drawing may not be drawn to scale and may be different from the actual size and ratio for the sake of clarity of illustration.

### Fluid Handling Device

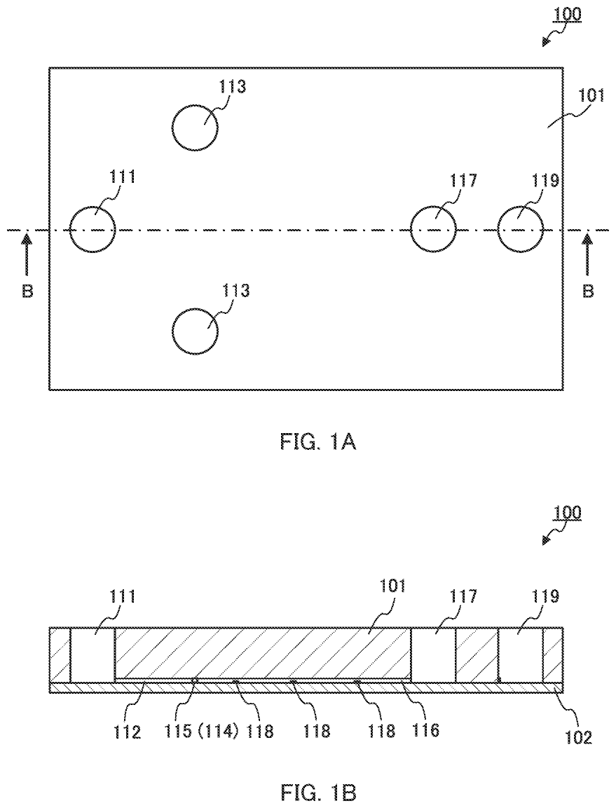

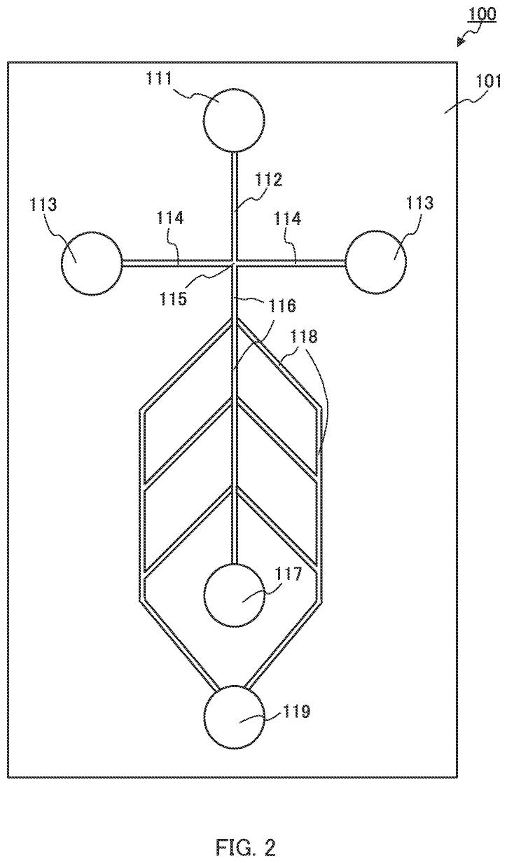

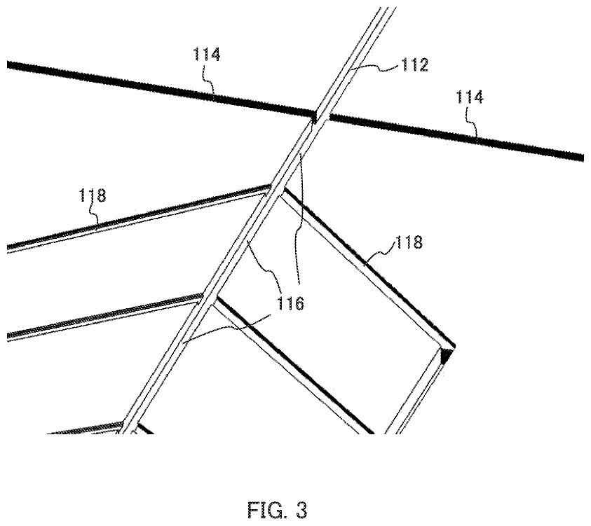

FIG. 1A is a plan view illustrating fluid handling device 100 according to an embodiment of the present invention, and FIG. 1B is a sectional view taken along line B-B of FIG. 1A. In addition, FIG. 2 is a bottom view illustrating substrate 101 of fluid handling device 100, and FIG. 3 is a partially enlarged perspective view of substrate 101.

As illustrated in FIG. 1B, fluid handling device 100 according to the embodiment of the present invention includes substrate 101 in which grooves and through holes are formed, and film 102 joined to one surface of substrate 101 to cover the openings of the grooves and the through holes. As illustrated in FIG. 1A to FIG. 3, fluid handling device 100 includes sample introduction part 111, sample channel 112, dispersion medium introduction part 113, dispersion medium channel 114, dispersion liquid generation part 115, dispersion liquid channel 116, dispersion liquid collection part 117, dispersion medium collection channel 118 and dispersion medium collection part 119. Note that sample introduction part 111, dispersion medium introduction part 113, dispersion liquid collection part 117, and dispersion medium collection part 119 are optional components. Each component is described below along the fluid flow.

Sample introduction part 111 is an inlet for introducing a sample into fluid handling device 100. In the present embodiment, sample introduction part 111 is composed of a through hole formed in substrate 101 and film 102 that closes one opening of the through hole. The structure of sample introduction part 111 is not limited as long as samples can be introduced to sample channel 112. In the present embodiment, sample introduction part 111 is a bottomed recess that can receive samples. In addition, the shape of sample introduction part 111 is also not limited. In the present embodiment, the shape of sample introduction part 111 is a columnar shape.

Sample channel 112 is connected to sample introduction part 111, and configured to carry the sample introduced to sample introduction part 111. In the present embodiment, sample channel 112 is composed of a groove formed in substrate 101 and film 102 that closes the opening of the groove. The structure of sample channel 112 is not limited as long as samples can be appropriately carried. In the present embodiment, sample channel 112 is a channel extending in the longitudinal direction of fluid handling device 100. The upstream end of sample channel 112 is connected to sample introduction part 111, and the downstream end of sample channel 112 is connected to dispersion liquid generation part 115.

The cross-sectional shape of sample channel 112 is not limited, and may be a semicircular shape, a rectangular shape, a circular shape or the like. The cross-sectional size of sample channel 112 is also not limited. Note that the “cross-section of a channel” as used herein means a cross-section orthogonal to the flow direction of the channel.

Dispersion medium introduction part 113 is an inlet for introducing a dispersion medium (e.g., oil) to fluid handling device 100. In the present embodiment, fluid handling device 100 is provided with two dispersion medium introduction parts 113, and each dispersion medium introduction part 113 is composed of a through hole formed in substrate 101 and film 102 that closes one opening of the through hole. The structure of dispersion medium introduction part 113 is not limited as long as the dispersion medium can be introduced to dispersion medium channel 114. In the present embodiment, dispersion medium introduction part 113 is a bottomed recess that can receive the dispersion medium. In addition, the shape of dispersion medium introduction part 113 is also not limited. In the present embodiment, dispersion medium introduction part 113 has a columnar shape.

Dispersion medium channel 114 is connected to dispersion medium introduction part 113, and configured to carry the dispersion medium (e.g., oil) introduced to dispersion medium introduction part 113. In the present embodiment, fluid handling device 100 is provided with two dispersion medium channels 114, and each dispersion medium channel 114 is composed of a groove formed in substrate 101 and film 102 that closes the opening of the groove. In the present embodiment, dispersion medium channel 114 is a channel extending in the short direction of fluid handling device 100. The upstream end of one dispersion medium channel 114 is connected to one dispersion medium introduction part 113, and the downstream end of one dispersion medium channel 114 is connected to dispersion liquid generation part 115. In addition, the upstream end of the other dispersion medium channel 114 is connected to the other dispersion medium introduction part 113, and the downstream end of the other dispersion medium channel 114 is connected to dispersion liquid generation part 115.

The cross-sectional shape of dispersion medium channel 114 is not limited, and may be a semicircular shape, a rectangular shape, a circular shape or the like. The cross-sectional size of dispersion medium channel 114 is also not limited.

Note that while the above-described fluid handling device 100 includes two dispersion medium introduction parts 113 and two dispersion medium channels 114, the number of dispersion medium introduction parts 113 and dispersion medium channels 114 is not limited, and may be, for example, one.

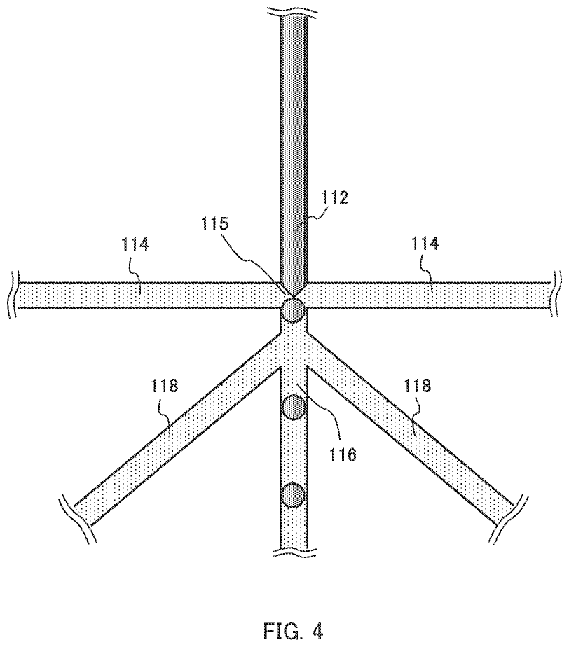

Dispersion liquid generation part 115 is connected to sample channel 112 and dispersion medium channel 114, and configured to divide the sample flowing through sample channel 112 by the dispersion medium flowing in from dispersion medium channel 114 to generate dispersion liquid in which droplets of the sample are dispersed in the dispersion medium. Dispersion liquid generation part 115 is formed by connecting dispersion medium channel 114 to sample channel 112. In the present embodiment, dispersion medium channels 114 are connected on the left and right sides of sample channel 112, and the sample flowing through sample channel 112 is divided by the dispersion medium flowing in from the left and right sides, and thus, droplets of the sample are generated (see FIG. 4).

The size of the opening (the downstream end of sample channel 112) of sample channel 112 at dispersion liquid generation part 115 is related to the size of the droplet, and typically, the diameter of the droplet is substantially equivalent to the opening of sample channel 112. In view of this, the size of (depth and width) of the opening of sample channel 112 is appropriately selected in accordance with the desired diameter of the droplet.

The size of the opening (the downstream end of dispersion medium channel 114) of dispersion medium channel 114 at dispersion liquid generation part 115 is related to the size, number, generation yield and the like of the droplet. In view of this, the size (depth and width) of the opening of dispersion medium channel 114 is appropriately selected in accordance with the type of the sample and the like.

Dispersion liquid channel 116 is a channel connected to dispersion liquid generation part 115 and configured to carry the dispersion liquid including droplets generated at dispersion liquid generation part 115. In the present embodiment, dispersion liquid channel 116 is composed of a groove formed in substrate 101 and film 102 that closes the opening of the groove. The structure of dispersion liquid channel 116 is not limited as long as droplets can be appropriately carried. In the present embodiment, dispersion liquid channel 116 is a channel that is contiguous with the sample channel 112 and extends in the longitudinal direction of fluid handling device 100. The upstream end of dispersion liquid channel 116 is connected to dispersion liquid generation part 115, and the downstream end of dispersion liquid channel 116 is connected to dispersion liquid collection part 117.

The cross-sectional shape of dispersion liquid channel 116 is not limited, and may be a semicircular shape, a rectangular shape, a circular shape or the like. Preferably, the cross-sectional size (depth and width) of dispersion liquid channel 116 is greater than the cross-sectional size (depth and width) of sample channel 112 so as not to hinder the movement of droplets.

Dispersion liquid collection part 117 is an outlet connected to dispersion liquid channel 116 and configured to collect the dispersion liquid containing droplets. In the present embodiment, dispersion liquid collection part 117 is composed of the through hole formed in substrate 101 and film 102 that closes one opening of the through hole. The structure of dispersion liquid collection part 117 is not limited as long as the dispersion liquid containing droplets can be collected. In the present embodiment, dispersion liquid collection part 117 is a bottomed recess that can house the dispersion liquid. In addition, the shape of dispersion liquid collection part 117 is also not limited. In the present embodiment, dispersion liquid collection part 117 has a columnar shape. While the size of dispersion liquid collection part 117 may be appropriately set in accordance with the amount of the dispersion liquid to be collected, fluid handling device 100 according to the present embodiment can reduce the amount of the dispersion medium in the dispersion liquid. Thus, the size of dispersion liquid collection part 117 can be relatively reduced.

Dispersion medium collection channel 118 is a channel connected to dispersion liquid channel 116 and configured to collect the dispersion medium from the dispersion liquid flowing through dispersion liquid channel 116. In the present embodiment, fluid handling device 100 includes six dispersion medium collection channels 118 (two dispersion medium collection channels 118 after the confluence), and each dispersion medium collection channel 118 is composed of a groove formed in substrate 101 and film 102 that closes the opening of the groove. The upstream end of dispersion medium collection channel 118 is connected to dispersion liquid channel 116, and the downstream end of dispersion medium collection channel 118 is connected to dispersion medium collection part 119. The number of dispersion medium collection channels 118 may be appropriately selected in accordance with the amount of the oil to be collected, and may be one or a plurality of dispersion medium collection channels 118 may be provided.

Preferably, dispersion medium collection channel 118 includes a portion narrower than dispersion liquid channel 116, or more specifically, a portion narrower than the diameter of the droplet, for preventing passage of droplets. With such a portion, it is possible to collect only the dispersion liquid from dispersion liquid channel 116 to increase the concentration of the droplets in the dispersion liquid flowing inside the dispersion liquid channel 116. From the viewpoint of preventing entry of the droplet into dispersion medium collection channel 118, the portion of narrower than dispersion liquid channel 116 in dispersion medium collection channel 118 is preferably disposed at the connecting part (the upstream end of dispersion medium collection channel 118) where dispersion medium collection channel 118 is connected to dispersion liquid channel 116.

FIG. 3 is a partially enlarged perspective view of substrate 101. FIG. 3 is a drawing illustrating a case where dispersion medium collection channel 118 includes a portion narrower than dispersion liquid channel 116. In FIG. 3, the portion is disposed at the connecting part (the upstream end of dispersion medium collection channel 118) where dispersion medium collection channel 118 is connected to dispersion liquid channel 116. In addition, the depth of dispersion medium collection channel 118 is smaller than the depth of dispersion liquid channel 116, and thus dispersion medium collection channel 118 has a portion narrower than dispersion liquid channel 116. In addition, in FIG. 3, dispersion medium collection channel 118 is shallower than dispersion liquid channel 116 over the entire length of dispersion medium collection channel 118.

The configuration in which dispersion medium collection channel 118 includes a portion narrower than dispersion liquid channel 116 is not limited as long as passage of droplets can be prevented. Specifically, for example, the width of dispersion medium collection channel 118 may be smaller than the width of dispersion liquid channel 116, the depth of dispersion medium collection channel 118 may be smaller than that of dispersion liquid channel 116, or a protrusion may be provided in a part of dispersion medium collection channel 118.

Dispersion medium collection part 119 is an outlet connected to dispersion medium collection channel 118 and configured to collect the dispersion medium. In the present embodiment, dispersion medium collection part 119 is composed of a through hole formed in substrate 101 and film 102 that closes one opening of the through hole. The structure of dispersion medium collection part 119 is not limited as long as the dispersion medium can be collected. In the present embodiment, dispersion medium collection part 119 is a bottomed recess that can house the dispersion medium. In addition, the shape of dispersion medium collection part 119 is also not limited. In the present embodiment, dispersion medium collection part 119 has a columnar shape. The size of dispersion medium collection part 119 may be appropriately set in accordance with the amount of the dispersion medium to be collected.

### Fluid Handling Method

Next, a method (fluid handling method) of generating and collecting a droplet of a sample using fluid handling device 100 according to the present embodiment is described.

First, a sample is introduced to sample introduction part 111, and a dispersion medium (e.g., oil) is introduced to two dispersion medium introduction parts 113.

The sample is, for example, liquid desired to be sorted as a droplet, or liquid containing a sort target material desired to be sorted in the state where it is enclosed in a droplet. Examples of the sample include liquids that contain cells, proteins, or nucleic acids. The sample may also contain a dispersion solvent to disperse a sort target material such as cells, proteins, or nucleic acids described above.

The dispersion medium is not limited as long as its compatibility with the sample is low and the sample flowing through sample channel 112 can be divided at dispersion liquid generation part 115.

The sample flows through sample channel 112 by being pressurized at sample introduction part 111, and flows through dispersion medium channel 114 by being pressurized at dispersion medium dispersion medium introduction part 113. Alternatively, the sample and the dispersion medium may be drawn into sample channel 112 and dispersion medium channel 114 by being depressurized at dispersion liquid collection part 117 and dispersion medium collection part 119.

As illustrated in FIG. 4, at dispersion liquid generation part 115, the sample flowing in from sample channel 112 is divided by the dispersion medium flowing in from two dispersion medium channels 114. In this manner, the sample becomes a droplet surrounded by the dispersion medium, and thus the dispersion liquid in which the droplet of the sample is dispersed in the dispersion medium is generated.

The dispersion liquid containing droplets flows through dispersion liquid channel 116 and reaches dispersion liquid collection part 117. At this time, droplets in the dispersion liquid cannot enter dispersion medium collection channel 118 connected to dispersion liquid channel 116, whereas the dispersion medium in the dispersion liquid can enter dispersion medium collection channel 118. The reason for this is that dispersion medium collection channel 118 includes a portion narrower than dispersion liquid channel 116 (a portion narrower than the diameter of a droplet) for preventing the passage of the droplet. In this manner, a part of the dispersion medium reaches dispersion medium collection part 119 through dispersion medium collection channel 118, and is then collected. On the other hand, the dispersion liquid with the increased concentration of the droplets reaches dispersion liquid collection part 117, and is then collected.

### Effect

With fluid handling device 100 according to the present invention, the droplets can be efficiently collected by increasing the concentration of the droplets in the dispersion liquid. Therefore, the required size of dispersion liquid collection part 117 can be reduced. In addition, the droplets can be efficiently collected even when the ratio of the oil flow rate to the sample flow rate (the oil flow rate/the sample flow rate) is increased.

### INDUSTRIAL APPLICABILITY

The fluid handling device of the embodiment of the present invention is applicable to laboratory tests, food tests, environment tests and the like, for example.

### REFERENCE SIGNS LIST

100 Fluid handling device
101 Substrate
102 Film
111 Sample introduction part
112 Sample channel
113 Dispersion medium introduction part
114 Dispersion medium channel
115 Dispersion liquid generation part
116 Dispersion liquid channel
117 Dispersion liquid collection part
118 Dispersion medium collection channel
119 Dispersion medium collection part

What is claimed is:

1. A fluid handling device comprising:
a sample channel configured to carry a sample;
a dispersion medium channel configured to carry a dispersion medium;
a dispersion liquid generation part connected to the sample channel and the dispersion medium channel and configured to generate dispersion liquid in which a droplet of the sample is dispersed in the dispersion medium by dividing the sample with the dispersion medium;
a dispersion liquid channel connected to the dispersion liquid generation part and configured to carry the dispersion liquid; and
a dispersion medium collection channel connected to the dispersion liquid channel and configured to collect the dispersion medium from the dispersion liquid flowing through the dispersion liquid channel.

2. The fluid handling device according to claim 1, wherein the dispersion medium collection channel includes a portion narrower than the dispersion liquid channel, the portion being configured to prevent passage of the droplet.

3. The fluid handling device according to claim 2, wherein the portion narrower than the dispersion liquid channel in the dispersion medium collection channel is disposed at a connecting part where the dispersion medium collection channel is connected to the dispersion liquid channel.

4. The fluid handling device according to claim 2, wherein a depth of the portion narrower than the dispersion liquid channel in the dispersion medium collection channel is smaller than a depth of the dispersion liquid channel.

5. The fluid handling device according to claim 1, wherein the portion narrower than the dispersion liquid channel in the dispersion medium collection channel is narrower than a diameter of the droplet.

6. The fluid handling device according to claim 1, wherein a plurality of the dispersion medium collection channels is provided.

7. The fluid handling device according to claim 1, further comprising:
a sample introduction part connected to the sample channel;
a dispersion medium introduction part connected to the dispersion medium channel;
a dispersion liquid collection part connected to the dispersion liquid channel; and
a dispersion medium collection part connected to the dispersion medium collection channel.
